(19) United States
(12) Patent Application Publication
(10) Pub. No.: US 2014/0240153 A1
(43) Pub. Date: Aug. 28, 2014

(54) ADVANCED OVERLOAD PROTECTION IN SIGMA DELTA MODULATORS

(71) Applicant: Abhijit Kumar Das, Dalas, TX (US)

(72) Inventor: Abhijit Kumar Das, Dalas, TX (US)

(73) Assignee: TEXAS INSTRUMENTS INCORPORATED, Dallas, TX (US)

(21) Appl. No.: 13/781,712

(22) Filed: Feb. 28, 2013

(51) Int. Cl. H03M 3/00

(52) U.S. Cl. CPC H03M 3/30
USPC 341/143

(57) ABSTRACT

A Sigma Delta Modulator (SDM) signal overload conditions are overcome without sacrificing performance or driving up implementation costs. These advanced overload protection method can be applied to any higher order SDM where overloading is a serious system concern.

### CLAIM OF PRIORITY UNDER 35 U.S.C. §119

This application claims the benefit of provisional patent application No. 61/604,184, filed Feb. 28, 2012, which is and assigned to the assignee hereof and hereby expressly incorporated herein by reference.

### FIELD

This disclosure relates generally to sigma delta modulators, and more particularly to circuits and methods for detecting and preventing signal overload conditions in sigma delta modulators.

### BACKGROUND

Electronic pulse modulator circuits convert an analog signal to a sequence of pulses suitable for processing in digital processing system. For some types of pulse modulators, the number of output pulses per unit of time represents the magnitude of the analog input. One common pulse modulator design is the Sigma-Delta Modulator (SDM), also known as a delta-sigma modulator (DSM).

FIG. 1A illustrates a simplified basic SDM 100. SDM 100 receives an analog input signal 102, generates a digital output signal 104 (which is binary in the example of FIG. 1A), and generates a feedback signal 106. A summing junction 108 combines the input signal and the feedback signal 106. The feedback signal is inverted, such that the summing junction 108 effectively subtracts the feedback signal 106 from the input signal 102, generating an error signal. An integrator (filter) 110 integrates the error signal. A quantizer 112 compares the integrated error signal to a threshold, and generates the digital output 104. In the example of FIG. 1A, the quantizer 112 is a single bit comparator generating a binary output. An analog switch 114 receives the digital output 104 and generates the feedback signal 106. In the example of FIG. 1A, the analog switch 114 selects one of two values (+V or −V) as the feedback signal, depending on the value of output 104. Sigma-delta modulators may have multiple stages (orders), and may generate a multi-level output, rather than the binary output of the single-order, single-level SDM circuit of FIG. 1A.

FIG. 1B illustrates a simplified, multi-level SDM 120. SDM 120 receives an input signal 122, generates an output signal 124, and generates a feedback signal 126. A summing junction 128 combines the input signal 122 and the feedback signal 126 to form an error signal. An integrator (filter) 130 integrates the error signal. A quantizer, shown here as a flash Analog-to-Digital Converter (ADC) 132, generates a digital output, depending on the magnitude of the integrated error signal. An analog switch 134 receives the output of the ADC and generates the feedback signal 126. Analog switch 134 selects one of three reference voltages (−V, 0, +V) as the feedback signal 126, depending on the output 124 of the flash ADC 132. Assume, for example, that the flash ADC 132 has two thresholds (one at +Vt and one at −Vt), and two output signals. A first output signal has a binary value of 1 when the input is greater than +Vt, and the second output signal has a binary value of 1 when the input is greater than −Vt. The output of the analog switch 134 is then +V when the first output signal is 1 (error signal >Vt). The output of the analog switch 134 is 0 when the first output signal is 0 and second output signal is 1 (i.e. −Vt <error signal<Vt); and the output of the analog switch is −V when the second output signal is 0 (i.e. the error signal <−Vt).

If the input signal to the SDM becomes higher than the designed limit, usually the feedback value, the residual error at the output of 128 and 108 can never reduce and the output of the filtering (integrating) network 130 and 110 will keep increasing. This may cause the comparator (112) or Flash ADC (132) to produce incorrect outputs and will in turn cause incorrect feedback (106 or 126). This regenerative process can cause the system to go in a sustained and stable oscillation mode. Once the system enters into this sustained oscillation mode, the output becomes almost independent of the input and performance is almost completely lost. This sustained oscillation mode can continue even when the stimulus (input signal magnitude) comes down to its pre-defined limit.

The order of the modulator is decided by the order of the filtering (integrating) network H(s). The higher this order the better is the performance. But increasing this order increases the possibility of sustained overloading of the system. A first order system (it has only one a single order integrator of filter in 110 or 130) will probably never have sustained oscillation. In a 2^{nd} order system we may or may not have sustained oscillation depending on the modulator design, but any higher order will have sustained overloading.

The overloading can be easily detected by monitoring the signal amplitude at various nodes (e.g. input or output of H(s)) of the integrating (filtering) network or by monitoring the output (104 and 124).

There is therefore a need in the art to handle overloads without sacrificing complete performance or driving up implementation costs.

### SUMMARY

Embodiments disclosed herein address the above stated needs by providing a novel Sigma Delta Modulator (SDM) architecture which overcomes the overloading issue without significant performance degradation or driving up implementation costs.

### BRIEF DESCRIPTION OF THE DRAWINGS

FIG. 1A is a block diagram illustrating an example prior art single-order, single-level, Sigma-Delta Modulator.

FIG. 1B is a block diagram illustrating an example prior art single-order, multi-level, Sigma-Delta Modulator.

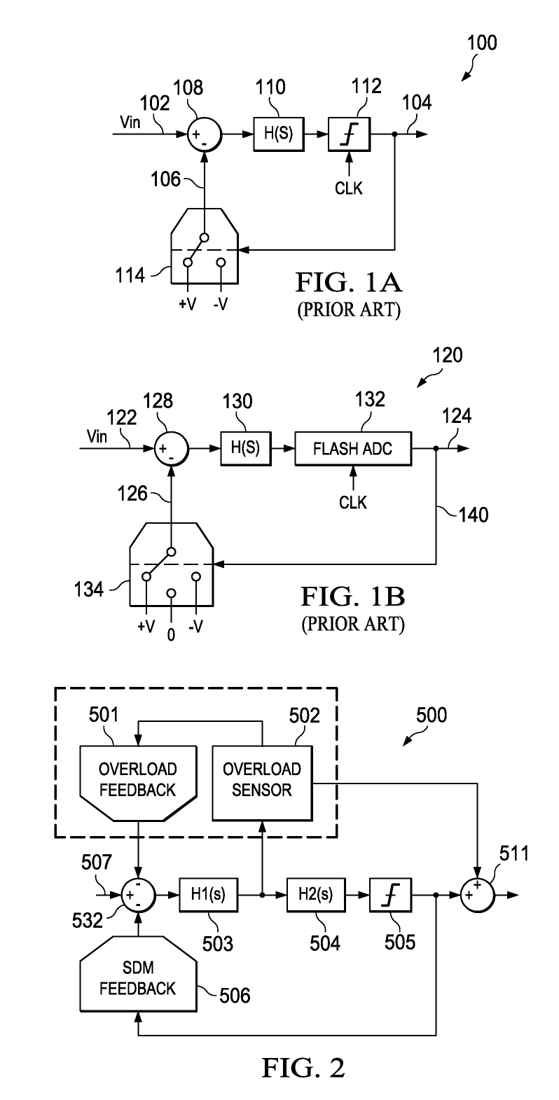

And FIG. 2 is a block diagram illustrating an exemplary alternative embodiment of an overload protection circuit for use with a sigma-delta modulator.

### DETAILED DESCRIPTION

Higher order SDMs provide higher performance using less power but are very limited by overload conditions. In typical communication systems, a large blocker often saturates the receiver requiring it to recover immediately to its normal operation mode. Depending on design modulators can demonstrate a sustained oscillation even when the overloading input signal is removed requiring the addition of a clamping circuit at the integrator nodes. However, it has traditionally been difficult to realize a sufficiently accurate and efficient clamping circuit. Also due to process variation, the clamping circuits often disturb normal operation mode creating unacceptable yield issues. Another very effective method of overload protection is to sense the overload by monitoring the ADC output or integrator output and “re-setting” the integrator accordingly. However, this ‘reset’ of the integrator raises the noise floor of the modulator significantly causing the modulator output to become un-usable.

Rather than clamping or integrator resetting, the present embodiment details another alternative embodiment of advanced overload protection. In this embodiment SDMs have simple sensor monitor(s) at the output of the first or second integrator. The sensor monitor(s) determine when the signal amplitude at the integrator output is higher than normal and whether the signal is positive or negative. When overload is detected, an additional feedback is applied to correct the residual error. The sensor provides the equivalent of a two level comparator where the middle level is sufficient for normal operation.

FIG. 2 is a block diagram illustrating an exemplary embodiment of an overload protection circuit used in conjunction with a sigma-delta modulator 500. The sigma-delta modulator 500 receives an input signal on line 507 at an adder 532, the output of which is directed through integrating filters 503 and 504. The order of filter H1(s) and H2(s) are decided based on implementation. For this novel protection method H1(s) has an upper limit of 2^{nd} order, whereas H2(s) can be of any order. The output of the integrating filter 504 is provided to the comparator 505. This comparator can be single bit or multi-bit depending on implementation. The output of this comparator is feedback through the usual feedback DAC 506.

The overload protection circuit 510 includes an overload sensor circuit 502 and an overload protection feedback 501. The overload sensor circuit 502 monitors the output of the first filter 503. If the absolute signal magnitude at the output of 503 is higher than desired (or higher than a preset limit) then it triggers an additional overload protection feedback 501. Depending on the sign of signal at output of 503 (i.e. if the signal is positive or negative) the direction (or sign) of the additional feedback is controlled. The magnitude of the additional feedback can be designed depending on requirement and design constraints. If the signal swing at the output of 503 is within the desired limit, no feedbacks or corrections are applied through 501.

This provides another input to the adder 532 in addition to the usual feedback 506. The residual error signal is then feed back to the filter 503. If the input signal increases beyond the capability of the normal SDM, the residual error keeps increasing the output of the integrating filters (503 and 504). This triggers the overload sensor and that in turn triggers the overload feedback. This overload feedback itself acts like another SDM feedback which increases the effective feedback strength and pushes the overload limit higher. This inherently limits further increase of the residual error signal magnitude at the integrating filters. A digital representation of this overload sensor output is added to the actual SDM output through adder 511. This overload protection scheme improves noise floor significantly during large (higher than designed) input signal condition for the SDM.

This overload protection circuit 510 behaves as a first or second order SDM by itself depending on the order of the filter H1(s) and protects the remaining loop filters from overload. Because the overload protection module 510, itself, is less than a second order (as the H1(s) can be a maximum of 2^{nd} order), it will return to normal operation by itself if forcefully overloaded.

As an example in a certain design the magnitude of the additional overload feedback 501 is designed to be ‘M’ times the normal SDM feedback 506. The SDM 500 will have normal performance till the input is close to the magnitude of feedback 506. In a normal SDM (where the novel overload protection scheme is not applied) any more increase in input signal amplitude will cause significant degradation or complete loss of the performance. With this novel protection, the SDM will maintain sufficient (slightly degraded) performance until the input signal increases to almost ‘M’ times higher. Beyond that the protection module may go into overload, but will come back as soon as the input signal is restored below ‘M’ times. The amplitude of the additional feedback determines the amount of input overdrive the SDM can tolerate. The larger this feedback, the more overdrive it can tolerate, but at the cost of a larger rise in the noise floor during overload.

The word “exemplary” is used herein to mean “serving as an example, instance, or illustration.” Any embodiment described herein as “exemplary” is not necessarily to be construed as preferred or advantageous over other embodiments.

Although the invention has been described and illustrated with a certain degree of particularity, it should be understood that the present disclosure has been made by way of example only, and that numerous changes in the combination and arrangement of parts may be resorted to without departing from the spirit and scope of the invention, as hereinafter claimed.

1. A sigma-delta modulator (SDM), comprising:
an integrator for integrating an SDM error signal to provide an SDM output;
an overload protection circuit to detect an overload condition of said integrator, and, if an overload condition is detected, to apply a feedback signal to increase a reference voltage of said SDM to keep a residual error within predetermined limits; and
a circuit to digitally combine said feedback signal with the SDM output, whereby said SDM is kept out of the overload condition.

2. The SDM of claim 1 further comprising:
a first summing junction configured to receive a modulator input signal and a system feedback signal, and to generate a system error signal by combining the input signal and the system feedback signal;
an amplifier for providing an amplified system feedback signal to the first summing junction;
and wherein said overload protection circuit comprises:
an overload sensor circuit to monitor an output of one of said feedback loops for an overload condition; and
an overload feedback protection circuit to product a feedback signal to said first summing junction if an overload condition is detected by said overload sensor circuit, thereby increasing a reference voltage of said SDM.

3. A method for providing signal overload protection in a sigma-delta modulator (SDM) comprising:
integrating an SDM error signal to provide an SDM output;
detecting on overload condition of said integrator;
if an overload condition is detected applying a feedback signal to effectively increase a reference voltage of said SDM to keep a residual error within predetermined limits; and
digitally combining said feedback signal with the SDM output to keep said SDM out of the overload condition.

4. The method of claim 3 where said effectively increasing said reference voltage of said SDM comprises subtracting said feedback signal from an SDM input signal.
